(19) United States
(12) Patent Application Publication
(10) Pub. No.: US 2025/0349628 A1
(43) Pub. Date: Nov. 13, 2025

(54) SILICON STRUCTURE TO MONITOR BITCELL PERFORMANCE

(71) Applicant: NVIDIA Corp., Santa Clara, CA (US)

(72) Inventors: Manish Umedlal Patel, Bangalore (IN); Karthik Balakrishnan, Bangalore (IN)

(73) Assignee: NVIDIA Corp., Santa Clara, CA (US)

(21) Appl. No.: 18/657,245

(22) Filed: May 7, 2024

(51) Int. Cl. H01L 21/66; G01R 23/02; H10B 10/00

(52) U.S. Cl. CPC H01L 22/34; G01R 23/02; H10B 10/00

(57) ABSTRACT

Silicon wafers including multiple wafer test structures, each comprising a ring oscillator comprising multiple bit-storing cells configured such that the discharge of a bitline triggers charging of a first adjacent bitline and discharge of a second adjacent bitline. The oscillation frequency of the ring oscillator changes in accordance with the discharge rate of the bitlines, which is affected by factors such as word line under-drive and aging. The silicon wafers include at least one frequency monitor coupled to one or more of the ring oscillators.

### BACKGROUND

Machine memory circuits, such as Static Random Access Memory (SRAM), are widely utilized in and by modern integrated circuits. Circuits such as SRAMs exhibit unique voltage-frequency (VF) characteristics than may be unlike the VF characteristics of other types of logic. Several types of ring oscillator circuits (based on inverters, NAND gates, NOR gates, etc.) are conventionally utilized to monitor the performance of logic circuits, but due to the unique VF characteristics of memory arrays, and in particular SRAM, there are a dearth of solutions to monitor SRAM performance across VF ranges.

Some conventional mechanisms track the monitor the SRAM access time or cycle time indirectly via the SRAM replica path (self-timing delay path). An oscillation loop is formed by generating feedback between the replica path and the clock fanout within the SRAM. However, this mechanisms does not provide precise metrics of the SRAM bit-storing cell properties. This is due at least in part to a large percentage of the replica path delay being attributable to logic devices other than the bit-storing cells themselves.

There is a need in the industry for in-silicon monitoring (ISM) structures that measure/monitor performance properties of the bit-storing cells used in circuits such as SRAMs, including discharge time, aging, statistical variation, and the impact of read assist on discharge time.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts a bit-storing cell monitoring circuit in one embodiment.

FIG. 2 depicts an example distribution of bit-storing cell monitoring circuits on an integrated circuit.

FIG. 3A depicts a bit-storing cell in one embodiment.

FIG. 3B a bit-storing cell in another embodiment.

FIG. 4 depicts aspects of a machine memory in one embodiment.

FIG. 5 a bitcell array and peripheral logic to form a ring oscillator in one embodiment.

FIG. 6 depicts signal timing for an embodiment of a bitcell array structure implementing a ring oscillator.

FIG. 7 depicts an embodiment of a structure wherein sixteen bitlines are coupled diagonally to form a ring oscillator structure.

FIG. 8 depicts a logic mechanism to place a ring oscillator into a calibration mode to measure the delay associated with peripheral logic components.

FIG. 9 depicts exemplary scenarios for use of a bit-storing cell monitoring circuit 902.

### DETAILED DESCRIPTION

Disclosed herein are area-efficient embodiments of in-silicon monitoring structures to measure attributes of bit-storing cells, for example in SRAM arrays. The structures generate signals indicative of the read current (Iread) utilized by the bit-storing cells and the associated statistical variation and aging impact thereof on the bit-storing cells. These signals may be applied in a number of ways for example to debug the memory circuits on production wafers and circuit die, to assist with SPICE (Simulation Program with Integrated Circuit Emphasis), to predict aging effects, to predict the impact of read assist on bit-storing cell performance, and in field applications to monitor impacts of aging and process, voltage, and temperature (PVT) on memory circuits.

The disclosed structures may be implemented as stand-alone ring oscillators configured such that the oscillation frequency is a metric of performance (e.g., discharge time) of the bit-storing cells. In one embodiment, a ring oscillator is formed by cascading a read operation diagonally across a memory array, e.g., an array of six-transistor memory cells or an array of eight-transistor memory cells. The system is configured such that bitline pre-charging does not influence the ring oscillator frequency.

Logic to operate the ring oscillators may comprise input/output gates, a decoder, and control logic. These components introduce additional delay that may be accounted for during a calibration mode. A mechanism is also introduced to measure the impact of various write line under-drive (WLUD) levels on bit-storing cell performance.

The bit-storing cell measurements may be enhanced and/or diversified for different operation conditions, by utilizing for example word line under drive read assist and/or by initializing the bit-storing cells with different data patterns.

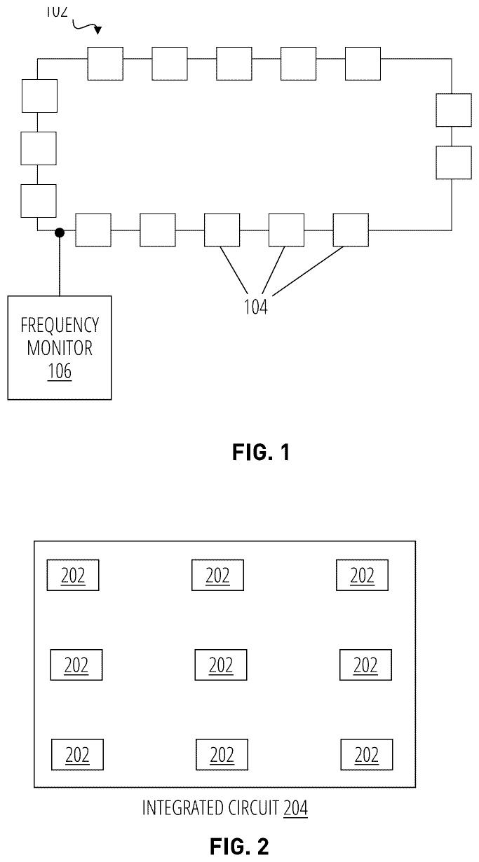

Bit-storing cell monitoring structures such as depicted in FIG. 1 to monitor bit-storing cell performance across varying read current and aging characteristics. A sequence of bit-storing cells 104 each on different word lines are configured into an oscillating ring in manner described in more detail below. FIG. 1 depicts a ring topology of the bit-storing cells 104; in practice the bit-storing cells 104 may be organized in a matrix configuration and operated via their word and bit lines in the manner of a ring oscillator.

Different read currents and aging factors influence the frequency of the ring oscillator 102, and these influences are detected by the frequency monitor 106. The ring oscillator may in some cases comprise an odd number of bit-storing cell stages (e.g., rows), in some cases a prime number of stages (a stage being a bitline and associated peripheral logic to charge and discharge the bitline). Generally, the number of stages may be any practical number.

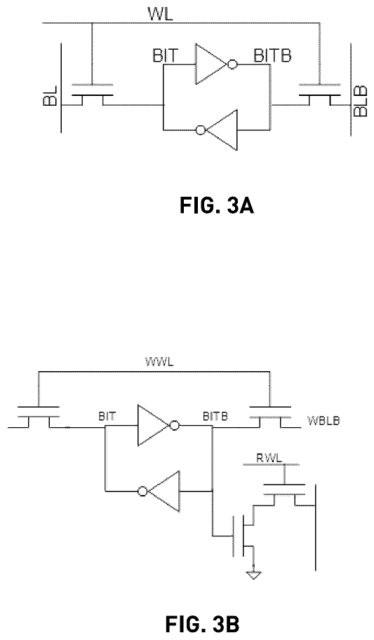

In one embodiment the bit-storing cells 104 are implemented as depicted in FIG. 3A (e.g., as SRAM cells with six transistors each, where WL represents a word line, BL a bitline, and BLB the complement bitline). In another embodiment the bit-storing cells 104 are implemented as depicted in FIG. 3B (e.g., SRAM cells with eight transistors each, where WWL represents the WRITE word line, RWL the READ word line). Generally, any bit-storing cell configuration may be utilized.

FIG. 2 depicts an example distribution of bit-storing cell monitoring circuits 202 on an integrated circuit 204. The bit-storing cell monitoring circuits 202 are disposed at different locations of the integrated circuit 204 where different operating conditions may occur, to model and monitor characteristics of bit-storing cells in each of those areas.

The bit-storing cell monitoring circuits 202 may be formed on a silicon wafer or other substrate as wafer acceptance testing (WAT) structures, also known as process control monitoring (PCM) circuits. The bit-storing cell monitoring circuits 202 may be operated to generate test results at the fabrication facility of the integrated circuit 204 for every wafer or selected subsets of wafers. Test results may be generated for each site (or “drop-in”) on the wafer where a bit-storing cell monitoring circuit 202 is formed.

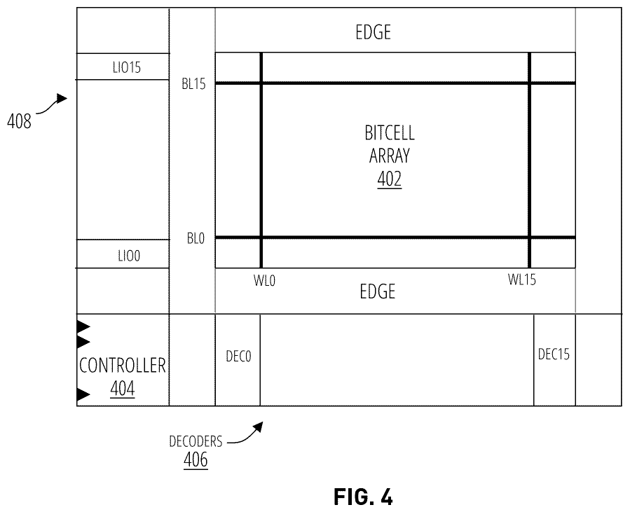

FIG. 4 depicts aspects of a machine memory in one embodiment. A bitcell array 402 is traversed by bitlines (BLx) and word lines (WLx). A controller 404 operates peripheral local IO logic 408 (LIOx) coupled to bitlines of the bitcell array 402, and address decoders 406 (DECx) operate word lines to read and write data from and to the bitcell array 402.

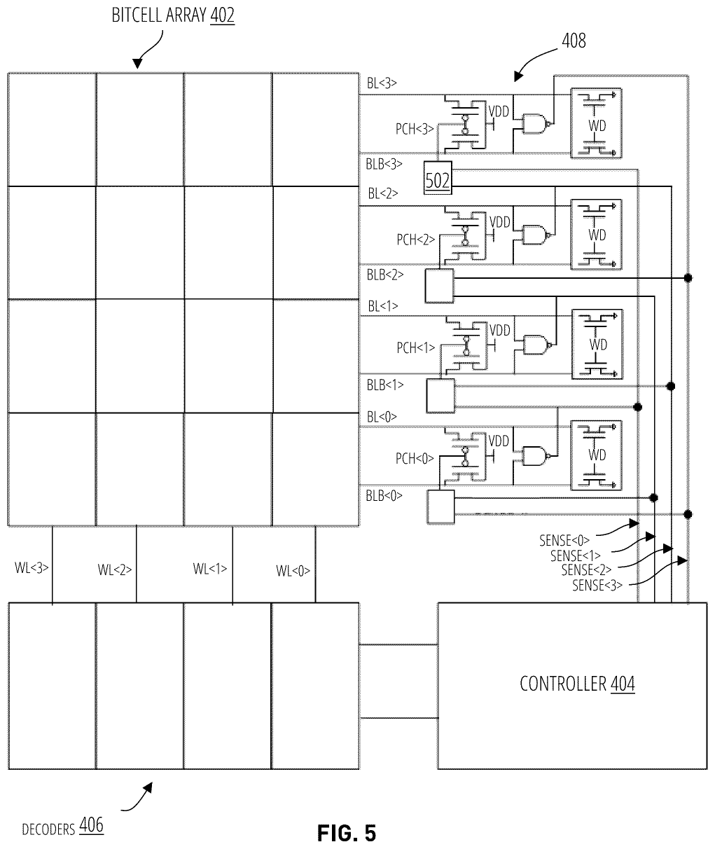

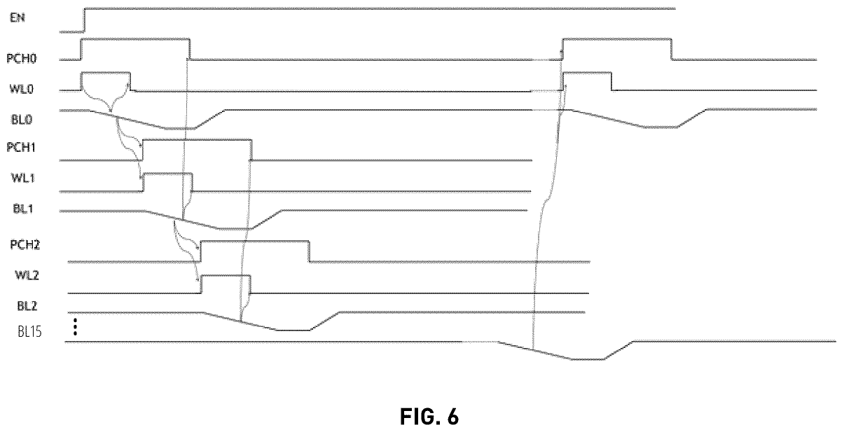

FIG. 5 depicts an exemplary embodiment comprising a 4×4 bitcell array 402, wherein the controller 404 and the local IO logic 408 are configured to operate the bitcell array 402 as a ring oscillator in accordance with the mechanisms described below. Each stage of the ring oscillator comprises pre-charge logic 502 to implement the oscillation. The pre-charge logic 502 may be readily implemented in numerous manners readily determined by those of ordinary skill in the art to carry out the pre-charge signaling as depicted and described in conjunction for example with FIG. 6.

FIG. 6 depicts signal timing for an embodiment of a memory array structure implementing a ring oscillator. Initially, the first bitline in the sequence, BL0, is high. When enable signal EN transitions from low to high, the word line 0 (WL0) for the first bitline (BL0) in the sequence transitions from low to high (turning ON). The precharge for bitline BL0, PCH0, also transitions from low to high (where a high value indicates turning OFF), causing BL0 to begin discharging.

The discharge of bitline BL0 below a threshold level triggers (e.g., in the controller 404) the word line WL1 of the next adjacent bitline BL1 to turn ON, and turns off the precharge PCH1 thereof, discharging bitline BL1. The discharge of bitline BL1 turns the precharge PCH0 of the previous bitline in the sequence, BL0, back ON (PCH0 transitions high to low), driving BL0 high again. In this manner, adjacent bitlines discharge in sequence and trigger the precharging of the previous bitline in the sequence.

Although depicted for the bitlines, similar timing may be utilized to generate the oscillation on the complement bitlines.

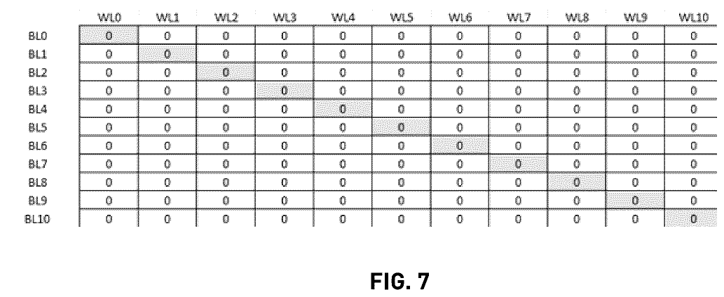

As noted above, for bitlines after the first one (BL0) in the sequence, precharging is triggered by the discharge of the next bitline in the sequence. The structure is configured such that the discharge of the last bitline in the sequence, e.g., BL15, triggers the precharging of the first bitline in the sequence, e.g., BL0. The charge and discharge of adjacent bitlines thereby sustains the oscillation of a ring structure. Due to the circular nature of the couplings, the first bitline (e.g., BL<0>) and the last bitline (e.g., BL<15>) in the array may also be understood to be adjacent in the ring oscillator thereby formed. The oscillation frequency depends on the bitline discharge rate and logic delay. FIG. 7 depicts an embodiment of a structure wherein a discharge pulse oscillates across 16 bitlines as described above.

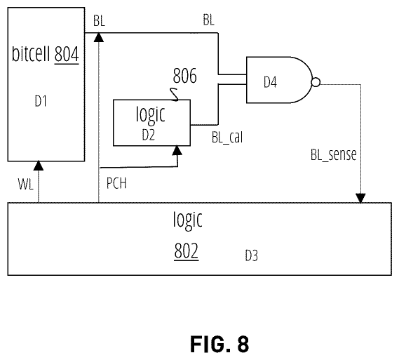

To improve measurement accuracy of the ring oscillator frequency, compensation may be added for the delay associated with peripheral logic 802 of the bit-storing cell 804 (e.g., the local IO logic 408, decoders 406, and/or controller 404 described in conjunction with FIG. 4). A logic mechanism to place the ring oscillator into a calibration mode may be added to measure the delay associated with the peripheral logic 802. An embodiment of such a logic mechanism is depicted in FIG. 8.

The period of oscillation during normal operation (Tₒ) is determined by the cumulative delay of the bitcell performance (e.g., discharge time) and the delay introduced by the peripheral logic:

Tₒ=D1+D4+D3

In calibration mode, the signal path between word lines and bitlines used during normal operation of the bit-storing cell 804 is bypassed and a delay D2 of calibration logic 806 is inserted. When calibration mode is set, the oscillation period becomes:

T_{c}=D2+D4+D3

At the bit-storing cell 804, the word line signal WL and the pre-charge signal PCH arrive approximately together, so that the delay between assertion of WL and PCH and assertion of BLₛₑₙₛₑ is:

D1=Tₒ−T₁+D2

The delay D2 may be configured as a one-stage delay that may be estimated from simulation, or ignored entirely due to being negligible. The difference Tₒ−T₁ may be measured to determine the compensation factor for the peripheral logic 802.

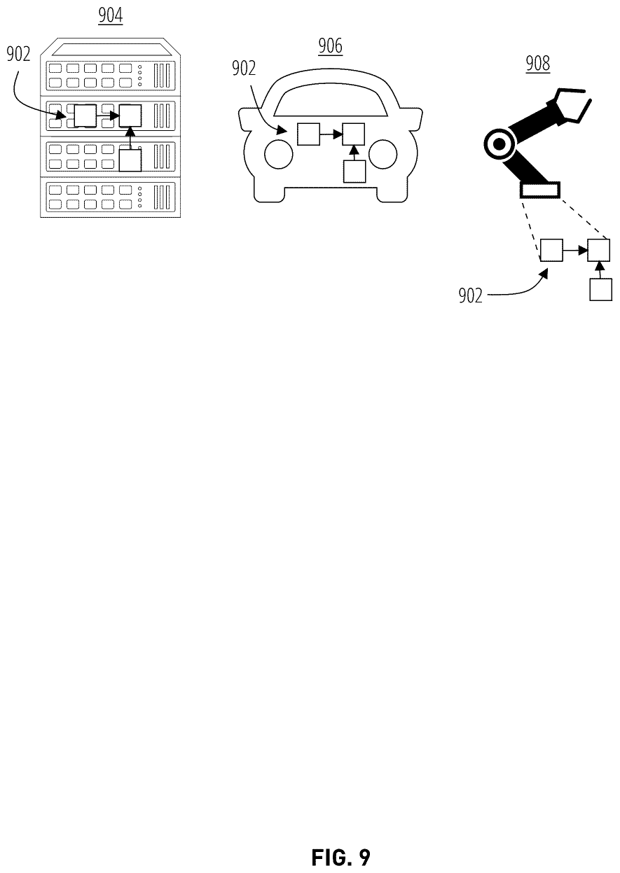

FIG. 9 depicts exemplary field-use scenarios for use of a bit-storing cell monitoring circuit 902. These applications are in addition to the wafer-test applications described above. A bit-storing cell monitoring circuit 902 may be utilized in a computing system 904, a vehicle 906, and a robot 908, to name just a few examples. The bit-storing cell monitoring circuit 902 may comprise ring oscillator circuit(s) in accordance with the mechanisms described herein.

### LISTING OF DRAWING ELEMENTS

102 ring oscillator
104 bit-storing cell
106 frequency monitor
202 bit-storing cell monitoring circuit
204 integrated circuit
402 bitcell array
404 controller
406 decoder
408 local IO logic
502 pre-charge logic
802 peripheral logic
804 bit-storing cell
806 logic
902 bit-storing cell monitoring circuit
904 computing system
906 vehicle
908 robot

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S.C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the intended invention as claimed. The scope of inventive subject matter is not limited to the depicted embodiments but is rather set forth in the following Claims.

What is claimed is:

1. A circuit comprising:
a frequency monitor coupled to a ring oscillator; and
the ring oscillator comprising a plurality of bit-storing cells configured such that the discharge of a bitline triggers charging of a first adjacent bitline and discharge of a second adjacent bitline.

2. The circuit of claim 1, the ring oscillator comprising a prime number of stages.

3. The circuit of claim 1, wherein the bit-storing cells are Static Random Access Memory (SRAM) cells.

4. The circuit of claim 3, wherein the SRAM cells are six-transistor cells.

5. The circuit of claim 3, wherein the SRAM cells are eight-transistor cells.

6. The circuit of claim 1, further comprising:
pre-charge logic for each of a plurality of stages of the ring oscillator; and
wherein the pre-charge logic for each stage of the ring oscillator is configured to activate in response to a bitline sense signal for a previous adjacent stage and a bitline sense signal for a subsequent adjacent stage.

7. The circuit of claim 1, further comprising:
calibration logic configured to determine a delay of peripheral logic of the bit-storing cells.

8. The circuit of claim 7, the calibration logic configured to:
determine a first oscillation period of the ring oscillator arising from a cumulative delay of discharge of the bit-storing cells and delay introduced by the peripheral logic; and
determine a second oscillation period of the ring oscillator arising from a delay of the peripheral logic and not including the delay of discharge of the bit-storing cells.

9. A silicon wafer comprising:
a plurality of wafer test structures, each of the plurality of wafer test structures comprising a ring oscillator comprising a plurality of bit-storing cells configured such that the discharge of a bitline triggers charging of a first adjacent bitline and discharge of a second adjacent bitline; and
at least one frequency monitor coupled to one or more of the ring oscillators.

10. The silicon wafer of claim 9, further comprising:
calibration logic configured to determine a delay of peripheral logic of the bit-storing cells.

11. The silicon wafer of claim 10, the calibration logic configured to:
determine a first oscillation period of the ring oscillator arising from a cumulative delay of discharge of the bit-storing cells and delay introduced by the peripheral logic; and
determine a second oscillation period of the ring oscillator arising from a delay of the peripheral logic and not including the delay of discharge of the bit-storing cells.

12. The silicon wafer of claim 9, wherein the bit-storing cells are Static Random Access Memory (SRAM) cells.

13. The silicon wafer of claim 12, wherein the SRAM cells are six-transistor cells.

14. The silicon wafer of claim 12, wherein the SRAM cells are eight-transistor cells.

15. The silicon wafer of claim 9, further comprising:
pre-charge logic for each of a plurality of stages of the ring oscillator; and
wherein the pre-charge logic for each stage of the ring oscillator is configured to activate in response to a bitline sense signal for a previous adjacent stage and a bitline sense signal for a subsequent adjacent stage.

16. A silicon wafer manufacturing process comprising:
forming on the silicon wafer a plurality of ring oscillators each comprising a plurality of bit-storing cells and stages, each of the stages configured such that the discharge of a bitline of the stage triggers charging of a bitline of a first adjacent stage and discharging of a bitline of a second adjacent stage; and
forming on the silicon wafer at least one frequency monitor coupled to one or more of the ring oscillators.

17. The silicon wafer manufacturing process of claim 10, the calibration logic configured to:
determine a first oscillation period of the ring oscillator arising from a cumulative delay of discharge of the bit-storing cells and delay introduced by the peripheral logic; and
determine a second oscillation period of the ring oscillator arising from a delay of the peripheral logic and not including the delay of discharge of the bit-storing cells.

18. The silicon wafer manufacturing process of claim 9, wherein each stage comprises pre-charge logic configured to activate in response to a bitline sense signal for a previous adjacent stage and a bitline sense signal for a subsequent adjacent stage.

19. The silicon wafer of claim 9, wherein the bit-storing cells are Static Random Access Memory (SRAM) cells.

20. The silicon wafer of claim 19, wherein the SRAM cells are one of six-transistor cells and eight transistor cells.
